(19) United States
(12) Patent Application Publication
(10) Pub. No.: US 2005/0236366 A1
(43) Pub. Date: Oct. 27, 2005

(54) Use of C2F6 gas to gain vertical profile in high dosage implanted poly film

(75) Inventor: Kuo-Chin Liu, Ji-an Township (TW)

Correspondence Address: DUANE MORRIS LLP;IP DEPARTMENT (TSMC), 4200 ONE LIBERTY PLACE, PHILADELPHIA, PA, 19103-7396, US

(73) Assignee: Taiwan Semiconductor Manufacturing Co.

(21) Appl. No.: 10/833,178

(22) Filed: Apr. 27, 2004

(51) Int. Cl. H01L 21/302; B44C 1/22

(52) U.S. Cl. 216/79; 216/58; 216/41; 216/74; 438/706

(57) ABSTRACT

A method of etching a polysilicon layer comprising the following steps. A polysilicon layer is formed over a structure and the polysilicon layer is etched using at least a C₂F₆ etching process to form an etched polysilicon layer having a vertical profile.

### FIELD OF THE INVENTION

The present invention relates generally to semiconductor fabrication and more specifically to etching poly films.

### BACKGROUND OF THE INVENTION

Polysilicon comprises a critical layer in semiconductor designs and its etched profile must be as vertical as possible. Some technology poly films have posted high dosage implanted levels for device requirements, but is difficult to control the vertical profile in etch chambers for higher implant level poly films.

Although bias power and bombardment gas, for example HBr, are used to control the etched poly film profile in etch chamber designs, sometimes this isn't sufficient and so-called necking issues persist.

U.S. Pat. No. 6,214,736 B1 to Rotondaro et al. describes a silicon processing method employing a plasma process which produces an undamaged and uncontaminated silicon surface by consuming silicon by continuous oxidation through a surface oxide layer and a simultaneous etch of the exposed silicon oxide surface.

U.S. Pat. No. 6,284,574 B1 to Petrarca et al. describes a structure and process for facilitating the conduction of heat away from a semiconductor device.

U.S. Pat. No. 6,133,156 to Langley describes an anisotropic etch method.

### SUMMARY OF THE INVENTION

Accordingly, it is an object of one or more embodiments of the present invention to provide an improved method of etching polysilicon films to achieve vertical-etch profiles.

Other objects will appear hereinafter.

It has now been discovered that the above and other objects of the present invention may be accomplished in the following manner. Specifically, a polysilicon layer is formed over a structure and the polysilicon layer is etched using at least a C₂F₆ etching process to form an etched polysilicon layer having a vertical profile. The etched polysilicon layer having an upper surface.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 to 3 schematically illustrate a preferred embodiment of the present invention.

### DETAILED DESCRIPTION OF THE PREFERRED EMBODIMENT

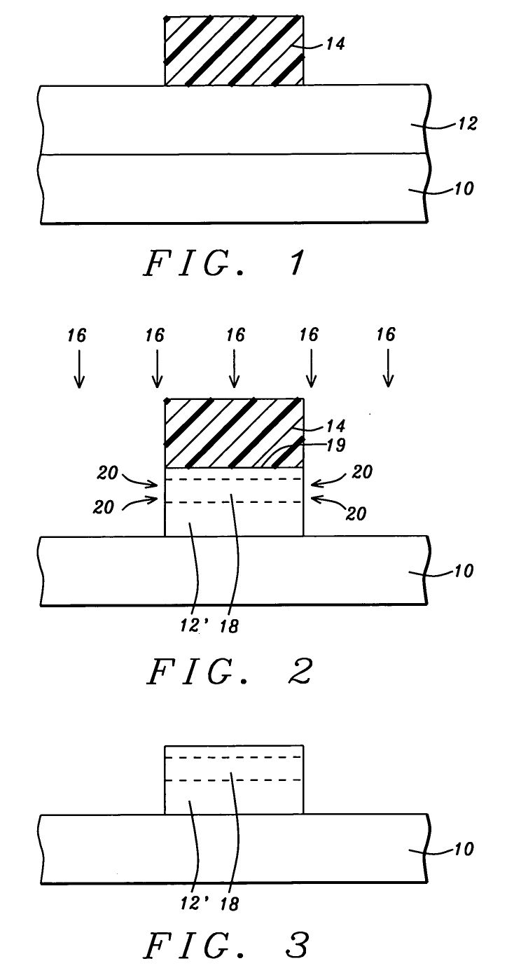

Initial Structure—FIG. 1

As shown in FIG. 1, a structure 10 includes an overlying dielectric film 12 that is preferably comprised of polysilicon, doped polysilicon or amorphous silicon and is more preferably polysilicon as will be used for illustrative purposes hereafter. Polysilicon film 12 has a thickness of preferably from about 1500 to 3000 Å and more preferably from about 1800 to 2000 Å.

Structure 10 is preferably a silicon substrate and is understood to possibly include a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer.

A patterning masking layer 14 may be formed over polysilicon film 12. Masking layer 14 is preferably comprised of photoresist or an oxide mask and is more preferably photoresist.

Etching of Polysilicon Layer 12—FIG. 2

As shown in FIG. 2, polysilicon layer 12 is patterned using an etch process 16 employing C₂F₆ gas at preferably from about 10 to 90 sccm and more preferably from about 10 to 40 sccm under the following further conditions:
total pressure: preferably from about 4 to 25 mTorr and more preferably from about 8 to 20 mTorr;
temperature: preferably from about 50 to 70° C. and more preferably from about 63 to 67° C.;
time: preferably from about 20 to 80 seconds and more preferably from about 30 to 60 seconds;
bias power: preferably from about 80 to 200 W and more preferably from about 80 to 150 W;
Cl₂ gas: preferably from about 10 to 100 sccm and more preferably from about 10 to 40 sccm;
HBr gas: preferably from about 100 to 250 sccm and more preferably from about 150 to 200 sccm;
He gas: preferably from about 50 to 150 sccm and more preferably from about 80 to 120 sccm;
O₂ gas: preferably from about 0 to 5 sccm and more preferably from about 0 to 3 sccm; and
source power: preferably from about 200 to 400 W and more preferably from about 250 to 350 W.

The ratio of C₂F₆:Cl2 is preferably from about 1:8 to 2:3.

Etch process 16 is preferably a two step process, that is a first step consisting of a C₂F₆-containing etch step to achieve a high dosage implanted polysilicon film/layer 12′ structure and a second step consisting of a Cl₂-containing etch step to solve C₂F₆ polymer rich issue, i.e. C₂F₆ gas will produce much polymer residue. The second step Cl₂-containing etch step uses an endpoint mode type to prevent substrate 10 damage issue.

The second step Cl₂-containing etch step employing a Cl₂, He, HBr and O₂-containing gas to prevent chamber polymer condition over high issue, i.e. a high chamber polymer is not good. The higher polymer condition, taper profile is generated easily as opposed to the desired vertical profile.

Polysilicon layer 12 may be patterned using, for example, patterned masking layer 14 as a mask as shown in FIG. 2.

As shown in FIG. 2, as polysilicon layer 12 is etched to formed etched polysilicon layer 12′, passivation ions, i.e. those ions that would form polymer on the film/layer 12 surface to generate vertical profile, are implanted into the polysilicon layer 12 as at 20 to form a passivation layer portion 18 within etched polysilicon layer 12′.

The passivation ions are preferably C₂F₆, C₄F₈ or CF₄ and are more preferably C₂F₆.

Passivation layer portion 18 has a passivation ion concentration of preferably from about 100 to 100,000 atoms/cm³ and more preferably from about 1000 to 10,000 atoms/cm³ and is from about 100 to 1000 Å thick and is more preferably from about 300 to 800 Å thick.

Passivation layer portion 18 extends preferably from about 100 to 1000 Å and more preferably from about 300 to 800 Å beneath the upper surface 19 of the patterned polysilicon layer 12′

This passivation of polysilicon layer 12 during the C₂F₆ etch process 16 achieves a vertical profile of etched polysilicon layer 12′ as shown in FIGS. 2 and 3.

Further Processing—FIG. 3

As shown in FIG. 3, any patterned masking layer 14 is removed and the structure is cleaned as necessary. Further processing may then proceed.

### ADVANTAGES OF THE PRESENT INVENTION

The advantages of one or more embodiments of the present invention include the use of C₂F₆ gas to gain vertical profile in high dosage implanted poly film.

While particular embodiments of the present invention have been illustrated and described, it is not intended to limit the invention, except as defined by the following claims.

1. A method of etching a polysilicon layer, comprising the steps:
providing a structure;
forming a polysilicon layer over the structure; and
etching the polysilicon layer using at least a C₂F₆ etching process to form an etched polysilicon layer; the etched polysilicon layer having an upper surface and a vertical profile.

2. The method of claim 1, wherein the structure is a semiconductor structure, a silicon substrate, a semiconductor wafer or a semiconductor substrate.

3. The method of claim 1, wherein the polysilicon layer is doped polysilicon or amorphous silicon.

4. The method of claim 1, including the step of forming a patterned masking layer over the polysilicon layer.

5. The method of claim 1, including the step of forming a patterned masking layer over the polysilicon layer; the patterned masking layer being photoresist or an oxide mask.

6. The method of claim 1, wherein the C₂F₆ etching process employs from about 10 to 90 sccm of C₂F₆ gas.

7. The method of claim 1, wherein the C₂F₆ etching process employs from about 10 to 40 sccm of C₂F₆ gas.

8. The method of claim 1, wherein the C₂F₆ etching process passivates a portion of the etched polysilicon layer.

9. The method of claim 1, wherein the C₂F₆ etching process passivates a portion of the etched polysilicon layer; the passivated portion being from about 100 to 1000 Å thick.

10. The method of claim 1, wherein the C₂F₆ etching process passivates a portion of the etched polysilicon layer; the passivated portion being from about 300 to 800 Å thick.

11. The method of claim 1, wherein the C₂F₆ etching process passivates a portion of the etched polysilicon layer; the passivated portion being from about 100 to 1000 Å beneath the upper surface of the etched polysilicon layer.

12. The method of claim 1, wherein the C₂F₆ etching process passivates a portion of the etched polysilicon layer with passivation ions to a concentration of from about 100 to 100,000 atoms/cm³.

13. The method of claim 1, wherein the polysilicon layer is from about 1500 to 3000 Å thick.

14. The method of claim 1, further including etching the polysilicon layer with a second Cl₂ etching process after the C₂F₆ etching process.

15. The method of claim 1, wherein the C₂F₆ etching process employs a C₂F₆:Cl₂ ratio of from about 1:8 to 2:3.

16. A method of etching a polysilicon layer, comprising the steps:
providing a structure;
forming a polysilicon layer over the structure; and
etching the polysilicon layer:
a first time using a C₂F₆ etching process; and
a second time using a Cl₂, He, HBr and O₂ etching process to form an etched polysilicon layer; the etched polysilicon layer having an upper surface and a vertical profile.

17. The method of claim 16, wherein the structure is a semiconductor structure, a silicon substrate, a semiconductor wafer or a semiconductor substrate.

18. The method of claim 16, including the step of forming a patterned masking layer over the polysilicon layer, wherein the patterned masking layer is used as a mask when etching the polysilicon layer.

19. The method of claim 16, including the step of forming a patterned masking layer over the polysilicon layer, wherein the patterned masking layer is used as a mask when etching the polysilicon layer; the patterned masking layer polysilicon being photoresist or an oxide mask.

20. The method of claim 16, wherein the C₂F₆ etching process employs from about 10 to 90 sccm of C₂F₆ gas.

21. The method of claim 16, wherein the C₂F₆ etching process employs from about 10 to 40 sccm of C₂F₆ gas.

22. The method of claim 16, wherein the C₂F₆ etching process passivates a portion of the etched polysilicon layer.

23. The method of claim 16, wherein the C₂F₆ etching process passivates a portion of the etched polysilicon layer; the passivated portion being from about 100 to 1000 Å thick.

24. The method of claim 16, wherein the C₂F₆ etching process passivates a portion of the etched polysilicon layer; the passivated portion being from about 300 to 800 Å thick.

25. The method of claim 16, wherein the C₂F₆ etching process passivates a portion of the etched polysilicon layer; the passivated portion being from about 100 to 1000 Å beneath the upper surface of the etched polysilicon layer.

26. The method of claim 16, wherein the C₂F₆ etching process 16 passivates a portion of the etched polysilicon layer with passivation ions to a concentration of from about 100 to 100,000 atoms/cm³.

27. The method of claim 16, wherein the polysilicon layer is from about 1500 to 3000 Å thick.

28. The method of claim 16, wherein the C₂F₆ etching process employs a C₂F₆ : Cl₂ ratio of from about 1:8 to 2:3.

29. A method of etching a polysilicon layer, comprising the steps:
providing a semiconductor structure;
forming a polysilicon layer over the semiconductor structure; and
etching the polysilicon layer:
a first time using a C₂F₆ etching process employing from about 10 to 90 sccm of C₂F₆ gas; and
a second time using a Cl₂, He, HBr and O₂ etching process;
to form an etched polysilicon layer; the etched polysilicon layer having an upper surface and a vertical profile.

30. The method of claim 29, wherein the C₂F₆ etching process employs from about 10 to 40 sccm of C₂F₆ gas.

31. The method of claim 29, wherein the C₂F₆ etching process passivates a portion of the etched polysilicon layer.

32. The method of claim 29, wherein the C₂F₆ etching process passivates a portion of the etched polysilicon layer; the passivated portion being from about 100 to 1000 Å thick.

33. The method of claim 29, wherein the C₂F₆ etching process passivates a portion of the etched polysilicon layer; the passivated portion being from about 300 to 800 Å thick.

34. The method of claim 29, wherein the C₂F₆ etching process passivates a portion of the etched polysilicon layer; the passivated portion being from about 100 to 1000 Å beneath the upper surface of the etched polysilicon layer.

35. The method of claim 29, wherein the C₂F₆ etching process passivates a portion of the etched polysilicon layer; the passivated portion being from about 300 to 800 Å beneath the upper surface of the etched polysilicon layer.

36. The method of claim 29, wherein the C₂F₆ etching process passivates a portion of the etched polysilicon layer with passivation ions to a concentration of from about 100 to 100,000 atoms/cm³.

37. The method of claim 29, wherein the C₂F₆ etching process employs a C₂F₆ :Cl₂ ratio of from about 1:8 to 2:3.
